(19) United States
(12) Patent Application Publication
(10) Pub. No.: US 2007/0059917 A1
(43) Pub. Date: Mar. 15, 2007

(54) Printed circuit board having fine pattern and manufacturing method thereof

(75) Inventors: Jee-Soo Mok, Yongin-si (KR); Chang-Sup Ryu, Yongin-si (KR); Eung-Suek Lee, Ansan-si (KR); Ki-Hwan Kim, Boryeong-si (KR); Sung-Yong Kim, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/520,729

(22) Filed: Sep. 14, 2006

(30) Foreign Application Priority Data
Sep. 15, 2005 (KR) 10-2005-0086112

(51) Int. Cl. H01L 21/44; H01L 21/4763

(52) U.S. Cl. 438/613; 438/617; 438/618

(57) ABSTRACT

A manufacturing method for a printed circuit board having a fine pattern is disclosed, comprising: providing a carrier plate; coating the carrier plate with a photosensitive material; forming a first circuit pattern on the photosensitive material; forming a first circuit layer by drying a conductive paste printed into a space between the photosensitive materials where the first circuit pattern is formed; depositing an insulation layer on the first circuit layer; processing via holes penetrating the insulation layer; coating the insulation layer with the photosensitive material and then forming a second circuit pattern in the photosensitive material; forming a second circuit layer and filling the via holes by drying the conductive paste printed into a space between the photosensitive materials, where the second circuit pattern is formed, and the via holes; and removing the carrier plate.

### CROSS-REFERENCE TO RELATED APPLICATIONS

This application claims the benefit of Korean Patent Application No. 10-2005-0086112 filed with the Korean Intellectual Property Office on Sep. 15, 2005, the disclosures of which are incorporated herein by reference in their entirety.

### BACKGROUND

1. Technical Field

The present invention relates to a printed circuit board, in particular, to a printed circuit board having a fine pattern and a manufacturing method thereof using a conductive paste.

2. Description of the Related Art

A printed circuit board is typically fabricated by the following process: wiring either or both sides of a board formed of a variety of thermosetting synthetic resins with a copper wire; Mounting semiconductor chips, integrated circuits (IC) or electric components on the board and electrically wiring them; and coating with an insulating material. With advances in electric components, a multi-layer printed circuit board, manufactured by piling up the above printed circuit boards, has been introduced, and, Further, studies on design for interconnecting layers and insulating are being progressed for high densification of the multi-layer printed circuit board.

HDI (high density interconnection) substrate refers to a substrate to which such high-density circuit forming technologies are applied, and such HDI substrate maximizes the degree of freedom in designing for the interconnection between layers and the insulation, thereby improving its qualities and properties.

As a process of manufacturing a multi-layer printed circuit board, methods for forming a circuit with an electric wiring on each layer (namely, inner layer circuit or outer layer circuit involve an additive method, and a subtractive method.

The additive method forms a conductor pattern by selectively extracting a conductive material on an insulation substrate through electrolytic or electroless plating. The additive method is divided into a full-additive method and a semi-additive method according to whether or not there is a seed-layer for an electrolytic copper plating.

The subtractive method forms a conductive pattern by selectively removing unnecessary parts but a conductive material from an metal applied insulation substrate through an etching. Such a method is also called a tent and etch method, because the etching is performed after a tenting is performed on parts and holes where the conductive pattern will be formed.

FIGS. 1a to 1e illustrate a manufacturing process of a printed circuit board using the semi-additive method. FIGS. 2a to 2c are exemplary views showing circuit patterns of a printed circuit board according to a prior art.

Referring to FIG. 1a, a core layer having a thin copper layer 120 coated on both sides of a resin layer 110 is injected, and the core layer is thus called core CCL (copper clad laminates).

Referring to FIG. 1b, holes 130 are formed, so that the thin copper layers 120 are electrically connected with each other through the resin layer 110. The hole 130 may be inner via holes (IVH). A mechanical drill or a laser drill is used to process the hole 130. After the hole 130 is formed, copper plating 140 is formed by chemical copper plating or electrical copper plating.

As shown in FIG. 1c, the hole 130 is filled with an insulating resin, before an inner circuit 140 is formed.

As shown in FIG. 1d, an insulation layer 150 is deposited on the core layer where the inner layer circuit 140 is formed, and then via holes 160 are processed so that an outer circuit 170, which is later formed on the insulation layer 150, can be electrically connected with the inner circuit 140. The via hole 160 can be processed by employing a mechanical or laser drill.

A dry film, which belongs to photosensitive materials, is applied, and then a pattern for the outer layer circuit 170 is formed through exposing and developing in order to form the outer layer circuit 170.

Subsequently, as shown in FIG. 1e, after plating using the semi-additive method is performed on the pattern of the outer layer circuit 170, the dry film is exfoliated. A flash etching follows the foregoing, thereby forming the outer layer circuit 170.

Through repeating the above process, a multi-layer printed circuit board having four or six layers is produced.

In short, the circuit for a high density printed circuit board is formed by depositing a photosensitive material on an insulation material, followed by photoexposing and developing by using a circuit mask, and plating by the semi-additive method.

As a wet process requiring exfoliating the dry film, the above process has difficulty in forming a fine pattern for a printed circuit board of a package substrate, used in a high frequency device. Such drawbacks can be proved by FIGS. 2a to 2c, exemplary views of patterns in the printed circuit boards formed by the process described above.

Also, the dry film has at least a certain thickness (approximately, 25 μm), because it should be later exfoliated. Furthermore, the conductive pattern formed by the copper plating, namely, the outer layer circuit, is not adhered strongly, and the copper plating method is blamed to cause an environmental pollution. In addition, it takes a number of procedures to form the circuits, so that the lead time of the process is long and the manufacturing cost is high.

### SUMMARY

Accordingly, the present invention aims to provide a printed circuit board having a fine pattern by using a photosensitive material of high resolution and a manufacturing method thereof.

Also, the present invention aims to provide a printed circuit board having a fine pattern, the adhesive force of fine circuits of which is superior, since a photosensitive material is used without being exfoliated, and a manufacturing method thereof.

Also, the present invention aims to provide a printed circuit board having a fine pattern using a dry process using a paste, which is an environment-friendly process, instead of plating, and a manufacturing method thereof.

Further, the present invention aims to provide a printed circuit board having a fine pattern and a manufacturing method thereof, where via holes are filled with a conductive paste so that the via holes having even surfaces can be achieved.

Also, the present invention aims to provide a printed circuit board having a fine pattern and a manufacturing method thereof, which can provide excellent adhesion during the solder resist coating, resulting in high reliability since the surface is even in the surface treatment procedure following the completion of deposition.

One aspect of the present invention provides a manufacturing method for a printed circuit board having a fine pattern, comprising: providing a carrier plate; coating the carrier plate with a photosensitive material; forming a first circuit pattern on the photosensitive material; forming a first circuit layer by drying a conductive paste printed into a space between the photosensitive materials where the first circuit pattern is formed; depositing an insulation layer on the first circuit layer; processing via holes penetrating the insulation layer; coating the insulation layer with the photosensitive material and then forming a second circuit pattern in the photosensitive material; forming a second circuit layer and filling the via holes by drying the conductive paste printed into a space between the photosensitive materials, where the second circuit pattern is formed, and the via holes; and removing the carrier plate.

Here, the forming a first circuit pattern on the photosensitive material comprises: depositing a mask corresponding to the first circuit layer on the photosensitive material; illuminating a predetermined amount of light; and removing the mask and developing.

Also, the coating the insulation layer with the photosensitive material and then forming a second circuit pattern in the photosensitive material comprises: depositing a mask corresponding to the second circuit layer on the photosensitive material; illuminating a predetermined amount of light; and removing the mask and developing.

Further, the first and second circuit patterns each comprise an insulation pattern and a conductor pattern, and the insulation pattern is formed of embossed photosensitive material, and the conductor pattern is formed by filling a space between the insulation patterns with the conductive paste, and the thickness of the insulation pattern is the same or similar with that of the conductor pattern.

Also, the conductive paste is printed by a screen printing method.

Here, the thickness of the printed conductive paste is the same or similar with that of the photosensitive material forming the first or second circuit pattern by buffing.

Further, the photosensitive material has insulating properties.

Another aspect of the present invention provides a manufacturing method for a printed circuit board having a fine pattern comprising: fabricating a core layer by depositing a thin copper layer on a resin layer; forming an inner layer circuit in the core layer; depositing an insulation layer; coating the insulation layer with a photosensitive material; forming a fine pattern corresponding to an outer layer circuit in the photosensitive material, and forming via holes electrically connecting layers in the insulation layer; and forming the outer layer circuit and filling the via holes by drying the conductive paste printed in a space between the photosensitive materials, where the fine pattern is formed, and the via holes.

Here, forming a fine pattern corresponding to an outer layer circuit in the photosensitive material, and forming via holes electrically connecting layers in the insulation layer comprises: depositing a mask corresponding to the outer layer circuit on the photosensitive material; illuminating a predetermined amount of light; and developing after removing the mask.

Further, the conductive paste is printed by a screen printing method.

Here, the thickness of the printed conductive paste is the same or similar with that of the photosensitive material forming the fine pattern by buffing.

Also, the photosensitive material has insulating properties.

Another aspect of the present invention provides a printed circuit board having a fine pattern comprising: a core layer having an inner layer circuit formed by depositing a thin copper layer on a resin layer; an insulating layer deposited on the core layer; and an outer layer circuit layer having a conductor pattern formed of a conductive paste and disposed between insulation patterns formed of a photosensitive material on the insulation layer, the thickness of the conductor pattern being the same or similar with that of the insulation pattern.

Here, the photosensitive material has insulating properties.

Further, the printed circuit board further comprises via hole to electrically connect the core layer and the outer layer circuit layer, and the via holes are filled with the conductive paste.

Here, the conductive paste is screen printed to form the outer layer circuit layer and to fill the via holes.

Here, the thickness of the printed conductive paste is the same or similar with that of the photosensitive material by buffing.

Additional aspects and advantages of the present general inventive concept will be set forth in part in the description which follows, and in part will be obvious from the description, or may be learned by practice of the general inventive concept.

### BRIEF DESCRIPTION OF THE DRAWINGS

These and other features, aspects, and advantages of the present invention will become better understood with regard to the following description, appended claims, and accompanying drawings where:

FIGS. 1a to 1e illustrate a manufacturing process of a printed circuit board using the semi-additive method;

FIGS. 2a to 2c are exemplary views showing circuit patterns of a printed circuit board according to the semi-additive method;

FIGS. 3a to 3c illustrate a method for screen printing a conductive paste according to an embodiment of the present invention;

FIGS. 4a to 4i show a manufacturing method of a printed circuit board having a fine pattern of high density, which is formed by screen printing a conductive paste according to an embodiment of the present invention;

FIGS. 5a to 5c are exemplary views illustrating printed circuit boards using a conductive paste according to an embodiment of the present invention;

FIGS. 6a to 6g show a manufacturing process of a printed circuit board having a fine pattern of high density, which is formed by screen printing a conductive paste according to another embodiment of the present invention;

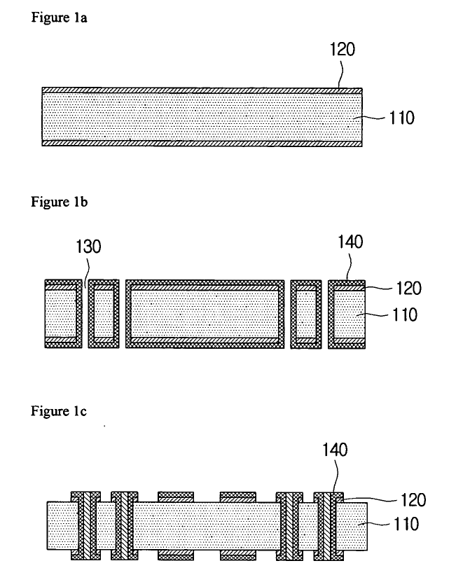

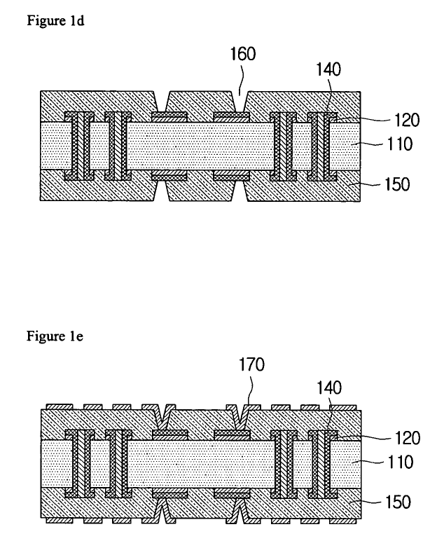

### DETAILED DESCRIPTION

In the present invention is employed a dry process using a conductive paste, instead of a wet process using a plating. Namely, a conductor pattern formed in each layer of a multi-layer printed circuit board is formed of the conductive paste not of copper plating, because of which, a photosensitive material, engraving the conductor pattern, has insulating properties.

A photosensitive material of high resolution is used to engrave the conductor pattern for circuit layers to which electric signals are transferred, except an insulation layer. The engraved conductor pattern is then filled with the conductive paste by a screen printing method, by which the circuit is completed. Through this process, the thickness of the circuit pattern can be thinner, and the height difference between the surface of the circuit pattern and wires the can be reduced. Consequently, more stable solder resist applying can be performed while surface treating, allowing a thin and uniform coating.

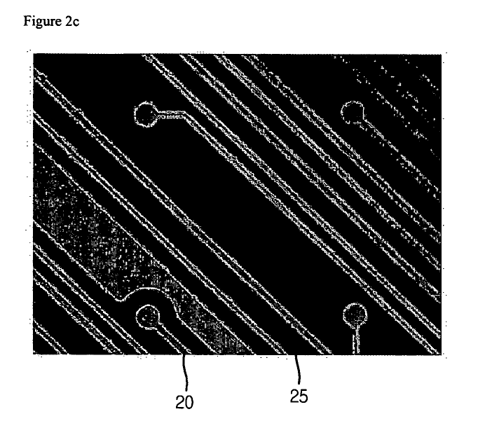

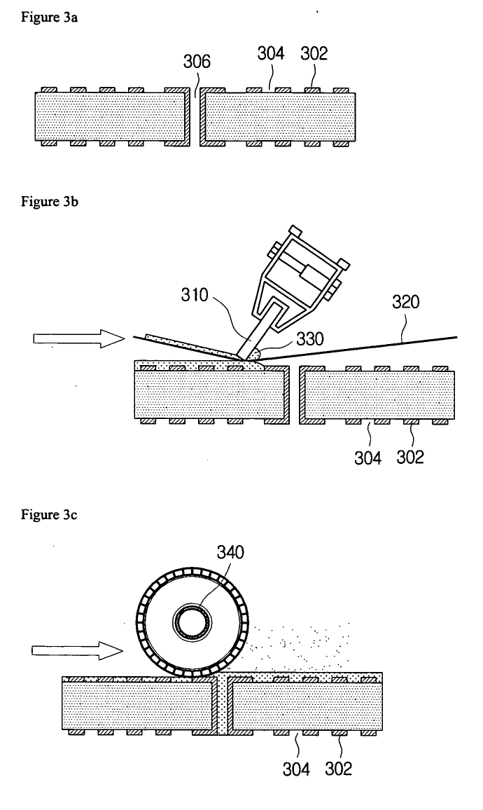

FIGS. 3a to 3c illustrate a method for screen printing a conductive paste according to an embodiment of the present invention. A printer, a dryer, an ultraviolet emission device, and a buffing machine are necessary for the screen printing, which does not incur an additional cost, because the aforementioned equipments are also employed in a typical manufacturing process of a printed circuit board.

With reference to FIG. 3a, there is a core layer, and a pattern is formed to form a circuit at the outside of the core layer. The circuit pattern is formed by the following procedures: Here, the circuit pattern consists of a conductor pattern to which electric signals are transferred, and an insulation pattern blocking electric signals.

An insulation layer is first deposited on the core layer. Next, a photosensitive material 302 of high resolution having insulating properties is applied or deposited on the insulation layer. Here, the high resolution is defined as enabling fine pattern (for example, 15/15 μm) formation when forming a circuit pattern. Accordingly, by using the photosensitive material 302 of high resolution, a circuit pattern having a fine pattern can be formed.

Then, the photosensitive material 302 undergoes photo-exposing/developing so that the insulation pattern is embossed, and the conductor pattern 304 is engraved: Regions where the photosensitive material 302 remains become the insulation pattern, regions 304 which are later coated with the conductive paste through screen printing become the conductor pattern.

Referring to FIG. 3b, the conductor pattern 304, shown in FIG. 3a, is coated with the conductive paste 330 by printing by employing a squeegee 310 and a screen 320. Also, a via hole 306, shown in FIG. 3a, is filled with the conductive paste 330 by printing.

The squeegee 310 moves in the arrow indicating direction of FIG. 3b so as to print and coat the core layer of FIG. 3a with the conductive paste 330 uniformly through the screen 320. At this time, the conductive paste 330 is preferably thicker than the photosensitive material 320 forming the insulation pattern on the core layer so as to cover the insulation pattern. The conductive paste 330 is then dried with heat. Because the paste is viscous, it should be hardened to be used on a printed circuit board. Accordingly, the conductive paste 330 is hardened through a heat drying process.

Afterward, as shown in FIG. 3c, the buffing machine 340 is used to grind the hardened conductive paste, by which the insulation pattern is shown to the outside. For this, the buffing machine 340 is set to stop grinding when the coated conductive paste becomes as thick as the photosensitive material.

Through the foregoing procedures is formed the conductor pattern by coating the surface of the printed circuit board on which a circuit pattern is formed with the conductive paste by screen printing.

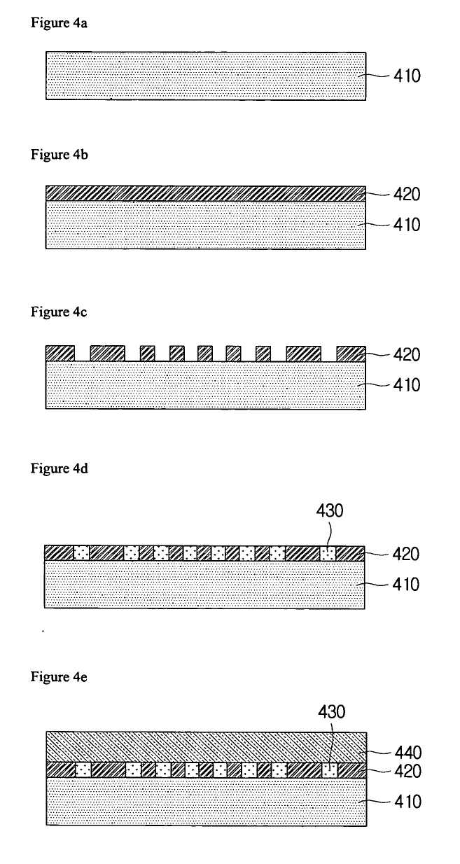

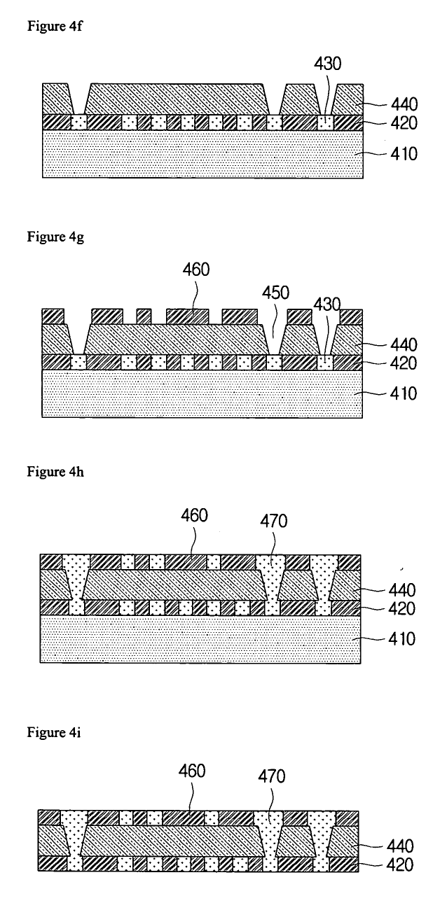

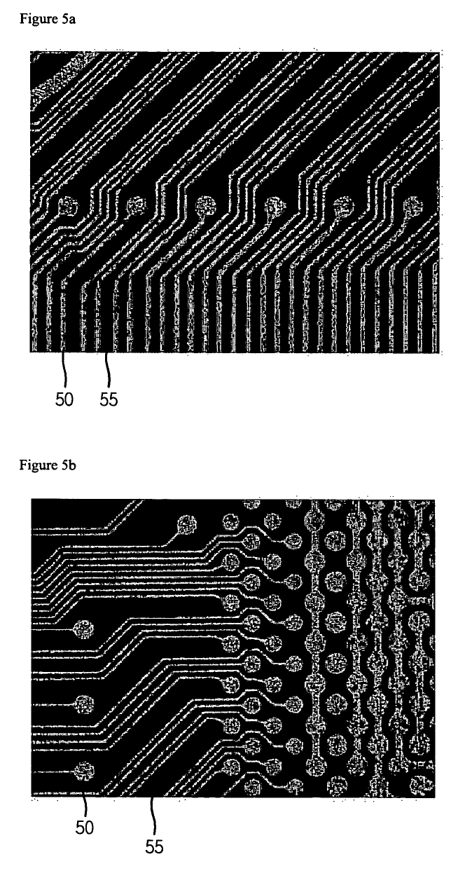

FIGS. 4a to 4i show a manufacturing process of a printed circuit board having a fine pattern of high density, which is formed by screen printing a conductive paste in accordance with an embodiment of the present invention;

As shown in FIG. 4a, a carrier plate 410, which is later removed, is provided to form a first circuit layer.

Referring to FIG. 4b, on the carrier plate 410 is deposited or applied a photosensitive material 420 having insulating properties, parts of which are hardened by being exposed to light, and the other parts are not hardened according to the amount of light. The photosensitive material 420 can be hardened in the opposite manner.

Referring to FIG. 4c, on the photosensitive material 420 is formed the circuit pattern, that is the insulation pattern and the conductor pattern, as a first circuit pattern. The photosensitive material 420 is embossed to form the insulation pattern, and engraved to form the conductor pattern, which is later filled with a conductive paste 430 by printing. The circuit pattern may be formed through mask stacking, photoexposing, and developing by using properties of the photosensitive material 420.

Here, the photosensitive material 420 has high resolution properties, thus capable of forming a pattern finer than a conventional pattern.

Referring to FIG. 4d, the engraved conductor pattern is filled with the conductive paste 430 by the screen printing method shown in FIGS. 3a to 3c, by which the first circuit pattern is composed of the conductor pattern filled with the conductive paste 430 transferring electric signals, and the insulation pattern formed of the photosensitive material 420 having insulating properties blocking electric signals. Here, the conductive paste 430 is hardened by heat, and is preferably grinded by the buffing machine so as to expose the photosensitive material 420 forming the insulation pattern to the outside.

Referring to FIG. 4e, on the first circuit layer is applied an insulating material 440 to divide layers. The insulating material 440 may be any material capable of blocking electric signals, such as resin, prepreg, and the like.

Referring to FIG. 4f, via hole 450 are processed to electrically connect the first circuit layer with a second circuit layer, which will be later formed. The via holea 450 are processed through a mechanical drilling or a laser drilling.

A photosensitive material 460 is applied or deposited on the insulation material 440, where the via hole 450 is processed, without covering the via hole 450.

A circuit pattern for the second circuit layer is formed through mask stacking, photoexposing, and developing. Because the photosensitive material 460 also has insulating properties, the insulation pattern is embossed, and the conductor pattern, which will be later filled with the conductive paste, is engraved.

As shown in FIG. 4h, the engraved conductor pattern and the via hole 450 are filled with the conductive paste 470 by the screen printing method of FIGS. 3a to 3c, by which the second circuit layer consists of the conductor pattern filled with the conductive paste 470 transferring electric signals, and the insulation pattern formed of the photosensitive material 460 having insulating properties blocking electric signals. Since the via hole 450, electrically joining the first and second circuit layers, is filled with the conductive paste 470, the first and second circuit layers are electrically connected with each other.

Here, the conductive paste 470 is hardened by heat drying, and is preferably grinded by the buffing machine so as to expose the photosensitive material 460 forming the insulation pattern to the outside.

As shown in FIG. 4i, after completing a double sided printed circuit board, the carrier plate 310 used to prevent the printed circuit board from bending is removed.

Consequently, the printed circuit board having the first and second circuit layers is fabricated through forming the conductor pattern by coating the conductive paste by employing the screen printing method, and forming the insulation pattern of the photosensitive material of high resolution..

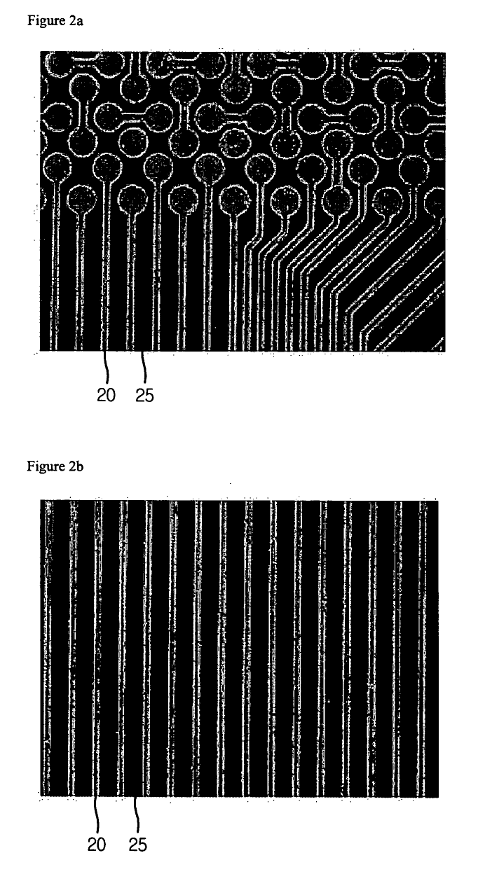

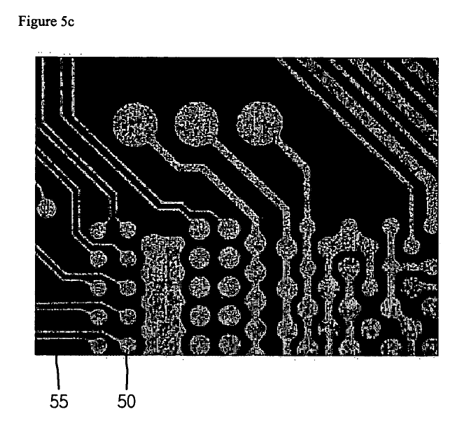

FIGS. 5a to 5c are exemplary views illustrating printed circuit boards using a conductive paste in accordance with an embodiment of the present invention, and enlarged in the same ratio with the views of FIGS. 2a to 2c.

In a printed circuit board, a circuit pattern, to which electric signals are transferred, composed of a conductor pattern 50 and an insulation pattern 55.

Compared to the conventional circuit patterns of FIGS. 2a to 2c, the conductor patterns 50 of FIGS. 5a to 5c are much thinner than the conductor pattern 20 of FIGS. 2a to 2c. Also, the insulation patterns FIGS. 5a to 5c filling gaps between the conductor patterns 50 is much thinner than the insulation patterns 25 of FIGS. 2a to 2c. Therefore, it can be seen that a circuit pattern having a finer circuit pattern than a conventional circuit pattern is formed.

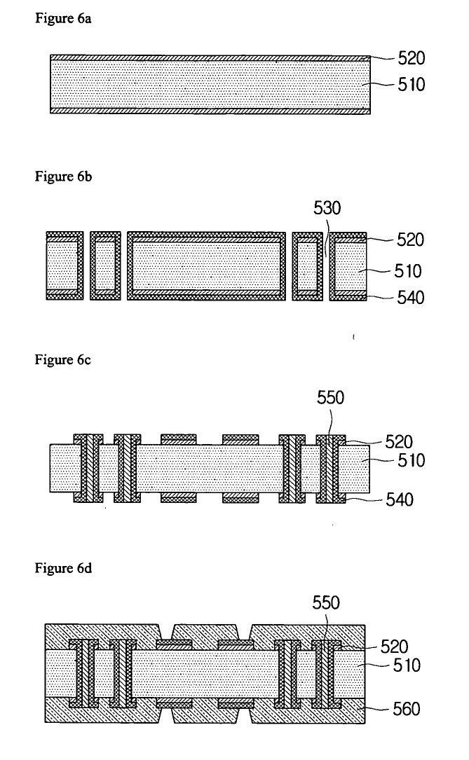

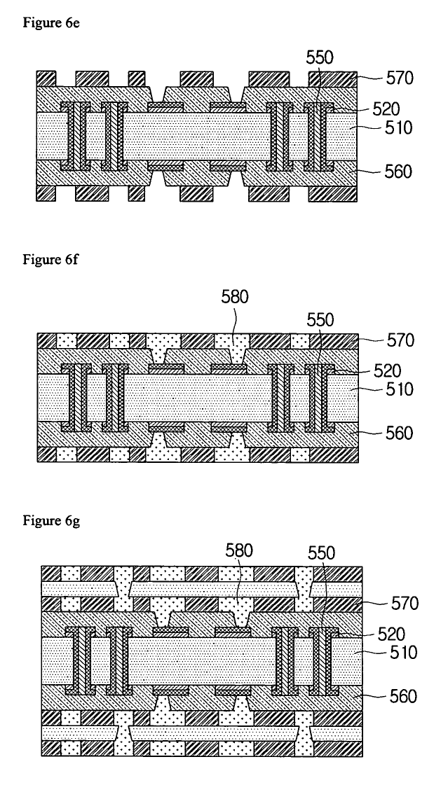

FIGS. 6a to 6g show a manufacturing method of a printed circuit board having a fine pattern of high density, which is formed by screen printing a conductive paste in accordance with another embodiment of the present invention

Referring to FIG. 6a, after any oxidized films and fingerprints formed on a CCL layer, having a resin layer 510 in the center and thin copper layers 520 on both side thereof, are removed, roughness is generated on the thin copper layer 520, to help a dry film adhere thereto strongly. Here, the roughness refers to any bumpy parts on the surface. The CCL layer undergoes mechanical and chemical grindings and brushing. Subsequently, a wash-cleaning or an ultra sonic process is performed on the CCL layer to remove remnants of copper, brush, and chemicals, and moisture remaining on the surface of the substrate and the hole is removed by using air. Then, the substrate is dried with hot air to enhance an adhesive force. Here, the resin layer 510 may be made of epoxy resin or polyimide resin of various thicknesses, and the thin copper layer 52 may be attached to only one side of the resin layer 510, if necessary.

As shown in FIG. 6b, holes 530 are processed so as to electrically connect the thin copper layers 520 on both sides of the CCL layer or inner and outer layers. The hole 530 is processed by a mechanical or laser drilling (namely, CO₂ or Nd-Yag laser drilling). Afterward, a plating 540 is performed by a chemical or electrical copper plating to form an inner layer circuit in the CCL layer.

Referring to FIG. 6d, the hole 530 of FIG. 6b is filled with an insulating resin, before the inner layer circuit is formed.

Afterward, referring to FIG. 6d, an insulating material 560 is deposited, and via holes through which the inner layer circuit is connected with the outer layer circuit are processed. The insulating material 560 may be a prepreg in a B state. The prepreg is a material used for an outer insulation layer in a multi-layer printed circuit board. The B-stage refers to an intermediate hardness of the prepreg, and in such stage, the prepreg can be transformed by heat and pressure over a certain threshold.

As shown in FIG. 6e, a photosensitive material 570 is applied or deposited on the insulation material 560 without covering the via holes of FIG. 6d. Next, the photosensitive material 570 is formed into the outer layer circuit through mask stacking, photoexposing, and developing. At this time, the photosensitive material 570 is engraved so as to leave only the insulation pattern of the circuit pattern forming the outer layer circuit, and the engraved parts become the conductor pattern, which is later filled with the conductive paste.

At this time, the photosensitive material 570 has insulating properties, thereby capable of blocking electric signals and forming a fine pattern.

Referring to FIG. 6f, the conductor pattern and the via holes are filled with the conductive paste 580 by the screen printing method illustrated in FIGS. 3a to 3c. Then, the conductive paste 580 is dried and grinded to make the surface even.

Referring to FIG. 6g, the process shown in FIGS. 6d to 6f can be repeated, by which a multi-layer printed circuit board is generated.

Afterward, a solder resist is applied and coated, and a solder is coated on the parts free of the solder resist to be connected with the outside, by which a surface treatment is completed.

Consequently, through the above is formed a printed circuit board comprising the core layer, having the inner layer circuit formed by depositing the thin copper layer on the surface of resin layer, and the insulation layer deposited on the core layer, and the outer layer circuit layer where the fine pattern is formed of the photosensitive material deposited on the insulation layer and the conductive paste.

Here, the printed circuit board may further comprise via holes through which the core layer and the outer layer circuit layer interconnect with each other, and the via hole is filled with the conductive paste. The conductive paste is screen printed to fill the via hole and to form the outer layer circuit layer, as shown in FIGS. 3a to 3c.

The thickness of the conductive paste is the same or similar with that of the photosensitive material, by which the insulation pattern formed of the photosensitive material is exposed to the outside so that the conductor patterns formed of the conductive paste can be insulated.

What is claimed is:

1. A manufacturing method for a printed circuit board having a fine pattern, comprising:
(a) providing a carrier plate;
(b) coating the carrier plate with a photosensitive material;
(c) forming a first circuit pattern on the photosensitive material;
(d) forming a first circuit layer by drying a conductive paste printed into a space between the photosensitive materials where the first circuit pattern is formed;
(e) depositing an insulation layer on the first circuit layer;
(f) processing via holes penetrating the insulation layer;
(g) coating the insulation layer with the photosensitive material and then forming a second circuit pattern in the photosensitive material;
(h) forming a second circuit layer and filling the via holes by drying the conductive paste printed into a space between the photosensitive materials, where the second circuit pattern is formed, and the via holes; and
(i) removing the carrier plate.

2. The manufacturing method for a printed circuit board having a fine pattern of claim 1, wherein the step (c) comprises: depositing a mask corresponding to the first circuit layer on the photosensitive material; illuminating a predetermined amount of light; and removing the mask and developing.

3. The manufacturing method for a printed circuit board having a fine pattern of claim 1, wherein the step (g) comprises: depositing a mask corresponding to the second circuit layer on the photosensitive material; illuminating a predetermined amount of light; and removing the mask and developing.

4. The manufacturing method for a printed circuit board having a fine pattern of claim 1, wherein the first and second circuit patterns each comprise an insulation pattern and a conductor pattern, and the insulation pattern is formed of embossed photosensitive material, and the conductor pattern is formed by filling a space between the insulation patterns with the conductive paste, and the thickness of the insulation pattern is the same or similar with that of the conductor pattern.

5. The manufacturing method for a printed circuit board having a fine pattern of claim 1, wherein the conductive paste is printed by a screen printing method.

6. The manufacturing method for a printed circuit board having a fine pattern of claim 5, wherein the thickness of the printed conductive paste is the same or similar with that of the photosensitive material forming the first or second circuit pattern by buffing.

7. The manufacturing method for a printed circuit board having a fine pattern of claim 1, wherein the photosensitive material has insulating properties.

8. A manufacturing method for a printed circuit board having a fine pattern comprising:
(a) fabricating a core layer by depositing a thin copper layer on a resin layer;
(b) forming an inner layer circuit in the core layer;
(c) depositing an insulation layer;
(d) coating the insulation layer with a photosensitive material;
(e) forming a fine pattern corresponding to an outer layer circuit in the photosensitive material, and forming via holes electrically connecting layers in the insulation layer; and
(f) forming the outer layer circuit and filling the via holes by drying the conductive paste printed in a space between the photosensitive materials, where the fine pattern is formed, and the via holes.

9. The manufacturing method for a printed circuit board having a fine pattern of claim 8, wherein the step (e) comprises: depositing a mask corresponding to the outer layer circuit on the photosensitive material; illuminating a predetermined amount of light; and developing after removing the mask.

10. The manufacturing method for a printed circuit board having a fine pattern of claim 8, wherein the conductive paste is printed by a screen printing method.

11. The manufacturing method for a printed circuit board having a fine pattern of claim 10, wherein the thickness of the printed conductive paste is the same or similar with that of the photosensitive material forming the fine pattern by buffing.

12. The manufacturing process for a printed circuit board having a fine pattern of claim 8, wherein the photosensitive material has insulating properties.

13. A printed circuit board having a fine pattern comprising:
a core layer having an inner layer circuit formed by depositing a thin copper layer on a resin layer;
an insulating layer deposited on the core layer; and
an outer layer circuit layer having a conductor pattern formed of a conductive paste and disposed between insulation patterns formed of a photosensitive material on the insulation layer, the thickness of the conductor pattern being the same or similar with that of the insulation pattern.

14. The printed circuit board having a fine pattern of claim 13, wherein the photosensitive material has insulating properties.

15. The printed circuit board having a fine pattern of claim 13, wherein the printed circuit board further comprises via hole to electrically connect the core layer and the outer layer circuit layer, and the via holes are filled with the conductive paste.

16. The printed circuit board having a fine pattern of claim 15, wherein the conductive paste is screen printed to form the outer layer circuit layer and to fill the via hole.

17. The printed circuit board having a fine pattern of claim 16, wherein the thickness of the printed conductive paste is the same or similar with that of the photosensitive material by buffing.
